(19) United States
(12) Patent Application Publication
(10) Pub. No.: US 2025/0279229 A1
(43) Pub. Date: Sep. 4, 2025

(54) MANUFACTURING METHOD FOR AN ELECTRICAL RESISTOR

(71) Applicant: Isabellenhütte Heusler GmbH & Co. KG, Dillenburg (DE)

(72) Inventor: Stefan DEGEN, Wetzlar (DE)

(73) Assignee: Isabellenhütte Heusler GmbH & Co. KG, Dillenburg (DE)

(21) Appl. No.: 18/855,619

(22) PCT Filed: May 9, 2023
(86) PCT No.: PCT/EP2023/062318

§ 371 Date: Oct. 9, 2024

(30) Foreign Application Priority Data
May 30, 2022 (DE) 10 2022 113 553.5

(51) Int. Cl. H01C 17/28; G01R 19/00

(52) U.S. Cl. CPC H01C 17/28; G01R 19/0092

(57) ABSTRACT

The invention relates to a manufacturing method for an electrical resistor (1), in particular for a low-resistance current measuring resistor, comprising the following steps:
Provision of a flat support element (2) made of a conductor material,
Provision of a flat resistor element (3) made of a resistor material,
applying the flat resistor element (3) to the upper side of the support element (2) with an electrically insulating layer (4) between the resistor element (3) and the support element (2), and
contacting the resistor element (3) by means of two contact caps (8, 9) made of a conductive material, the two contact caps (8, 9) resting directly on the upper side of the resistor element (3) and enclosing a specific distance (d) between them directly on the upper side of the flat resistor element (3) along the direction of current flow in the resistor (1), and
Specification of a desired resistance value of the resistor (1).

The manufacturing method according to the invention is characterised by the following step:
Adjusting the resistance value of the resistor (1) by setting the distance (d) between the contact caps (8, 9) directly on the upper side of the resistor element (3), wherein the distance (d) is set as a function of the desired resistance value.

### CROSS-REFERENCE TO RELATED APPLICATIONS

The present application is a 35 U.S.C. § 371 National Stage patent application of International patent application PCT/EP2023/062318, filed on May 9, 2023, which claims priority to German patent application DE 10 2022 113 553.5, filed on May 30, 2022, the entire contents of each of which are incorporated by referernce herein.

### BACKGROUND

### 1. Field of the Disclosure

The disclosure relates to a manufacturing method for an electrical resistor, in particular for a low-resistance current-measuring resistor.

### 2. Description of Related Art

WO 2008/055582 A1 discloses a low-resistance current-measuring resistor (“shunt”) and a manufacturing method for such a current-measuring resistor. As part of the manufacturing method, the resistance value is adjusted (“trimmed”) so that the finished current-measuring resistor maintains a specified resistance value as precisely as possible. This resistance adjustment is usually carried out by introducing a trimming cut into the resistor element of the current-measuring resistor, whereby the trimming cut influences the resistance value of the current-measuring resistor depending on its size and position. However, this known method for adjusting the resistance value of a current-measuring resistor has various disadvantages.

Firstly, it is difficult to realize resistance values with a very low tolerance of <0.5% in this way.

On the other hand, the incisions in the resistor element of the current-measuring resistor lead to a distortion of the current distribution in the resistor element, which can lead to local temperature increases (hot spots) in the resistor element during operation due to the electrical heat loss. Such localized temperature increases can impair the measurement accuracy, as the specific electrical resistance of the resistance material of the resistor element is temperature-dependent.

A further disadvantage of the known type of resistance adjustment is that the incision in the resistor element forms a mechanical weak point, which in extreme cases can lead to cracking under thermal stress due to expansion and compression.

Another disadvantage of the known types of resistance balancing is that different material removal for resistance balancing leads to fluctuations in the internal thermal resistance from component to component. This is not the case with adjustment by varying the contact distance.

Furthermore, the incision in the resistor element requires additional space, which limits the minimization of the component size of the current-measuring resistor.

Furthermore, the insertion of the incision in the resistor element can also lead to waste if the current measurement resistors show traces of machining or residues after the insertion of the incision.

With regard to the technical background of the disclosure, reference should also be made to CN 111 192 733 A1 and DE 30 27 122 A1.

The disclosure is therefore based on the task of indicating a correspondingly improved manufacturing method.

### Description of the Invention

This problem is solved by a manufacturing method according to the disclosure in accordance with the main claim.

The manufacturing method according to the disclosure corresponds in part to the known manufacturing method as described in WO 2008/055582 A1, so that the content of this publication is to be attributed in full to the present description with regard to the individual steps of the manufacturing method.

The manufacturing method according to the disclosure initially provides, in accordance with the prior art, that a flat support element is provided from an electrically conductive conductor material, wherein the support element has an upper side and a lower side.

The conductor material can be copper, for example, but the disclosure is not limited to copper with regard to the conductor material, but can also be realized with a copper alloy, aluminium or an aluminium alloy as conductor materials, for example.

It should also be mentioned that the support element preferably consists of a foil (e.g. copper foil), but the disclosure is not limited to foils with regard to the shape of the support element, but can also be realized with plate-shaped support elements, for example.

Furthermore, the manufacturing method according to the disclosure also provides, in accordance with the prior art, that a flat resistor element is provided from a resistor material.

The resistor material is, for example, a low-resistance resistor alloy, such as a copper-manganese-nickel alloy. However, the disclosure is not limited to a specific resistance material. However, the resistor material should have a greater specific electrical resistance than the conductor material of the support element.

It should also be mentioned that the flat resistor element preferably consists of a resistance foil. However, the disclosure is not limited to foils with regard to the shape of the resistor element, but can also be realized with plate-shaped resistor elements, for example.

In accordance with the prior art, the manufacturing method according to the disclosure also provides for the flat resistor element to be applied flat to the upper side of the flat support element, with an electrically insulating layer between the flat resistor element on the one hand and the flat support element on the other.

For example, the electrically insulating layer between the flat resistor element and the flat support element can be an adhesive layer, which thus fulfills two functions, namely on the one hand the mechanical connection between the support element and the resistor element and on the other hand the electrical insulation between the support element and the resistor element.

Furthermore, the manufacturing method according to the disclosure then provides, in accordance with the prior art, that the flat resistor element is electrically contacted by two contact caps, the two contact caps serving to make electrical contact with the finished resistor. The contact caps therefore consist of an electrically conductive conductor material. For example, the contact caps can be made of copper and have a tin coating. However, the contact caps do not necessarily have to be made of the same conductor material as the support element.

It should be mentioned here that the contact caps rest directly on the top of the resistor element and are opposite each other with regard to the direction of current flow in the resistor. In the finished resistor, the current to be measured therefore flows into the resistor through one contact cap, then flows through the resistor element and leaves the resistor again through the other contact cap.

It should also be mentioned here that there is a certain distance between the two contact caps directly on the upper side of the flat resistor element, whereby this distance influences the resistance value of the finished resistor. Thus, the distance between the two contact caps on the upper side of the resistor element defines the length of the current path through the resistor element and, therefore, also the resistance value of the finished resistor. However, this technical-physical relationship has not yet been utilized in the prior art to adjust the resistance value of the resistor.

In addition, the manufacturing method according to the disclosure also provides for a desired resistance value to be specified for the resistor, which is then taken into account in the resistance adjustment.

However, the disclosure is now characterized by a special type of resistance adjustment. In the context of the disclosure, the distance between the contact caps is set directly on the upper side of the resistor element to adjust the resistance value, whereby the distance is set as a function of the desired resistance value. For this purpose, tests can first be carried out to determine the relationship between the distance between the contact caps on the one hand and the resulting resistance value on the other. As part of the resistance adjustment according to the disclosure, this relationship can then be used to set the distance between the contact caps accordingly. The disclosure therefore no longer requires an incision in the resistor element for resistance adjustment, so that the disadvantages described at the beginning are avoided. For example, the method of resistance adjustment according to the disclosure allows smaller tolerances of <0.5% to be achieved and the temperature hotspots that are disturbing in the prior art can be avoided.

In a preferred embodiment of the disclosure, it is provided that solder resist is applied directly to the upper side of the resistor element before contact is made by the contact caps, the solder resists having only a certain extension along the direction of current flow in the resistor and leaving strips for the contact caps free at the opposite ends. The extension of the solder resist along the direction of current flow then defines the subsequent distance between the contact caps on the upper side of the resistor element and, thus, also the length of the current path through the resistor element. The contact caps are then applied to the top of the flat resistor element, whereby the contact caps then enclose the distance between them that was previously set by the solder resist. The contact caps can therefore be applied with relatively rough positioning tolerances, as the accuracy of the distance between the contact caps is defined by the extension of the previously applied solder resist.

It should also be mentioned that a solder resist can also be applied to the underside of the flat support element between the contact caps, as is known from the prior art. The solder resist on the underside of the support element can be applied either before or after the contact caps have been applied. However, the solder resist on the underside of the resistor is only optional.

In addition, the manufacturing method according to the disclosure preferably also provides for an incision to be made in the flat support element, the incision separating the flat support element into two parts so that the incision prevents a short circuit across the flat support element. This idea is also known, for example, from WO 2008/055582 A1. For example, this incision can be V-shaped, W-shaped, perpendicular or diagonal to the direction of current flow, as explained in the aforementioned publication.

It should also be mentioned that the incision in the flat support element is preferably filled with an electrically insulating material. On the one hand, this is advantageous because it increases the mechanical resilience of the resistor. On the other hand, filling with the insulating material is also advantageous in order to improve the dissipation of electrical heat loss.

The incision is preferably made in the flat support element before the solder resist has been applied to the underside of the flat support element, so that the solder resist also covers the incision with the insulation material inside. Alternatively, it is also possible that no solder resist is applied to the underside of the support element.

It has already been briefly mentioned at the beginning that the flat support element is preferably a metal foil, such as a copper foil, which is bonded to a resistance foil as a resistor element.

Furthermore, it should generally be mentioned that the contact caps preferably embrace the resistor on its upper side and underside. On the underside of the resistor, the contact caps can extend as far as the incision in the support element.

With regard to the terms “top side” and “bottom side” used in the context of the disclosure, it should be mentioned that these terms do not necessarily refer to the spatial orientation of the resistor during the assembly of a printed circuit board. Rather, these terms merely refer to the spatial orientation of the support element on the one hand and the resistor element on the other.

With regard to the resistor material, it has already been briefly mentioned above that a copper-fer-manganese-nickel alloy can be used, such as a copper-manganese-nickel alloy. The alloys CuMn12Ni (Manganin®), CuMn7Sn or CuMn3 are particularly suitable, to mention just a few examples. The resistor material can also be a nickel-chromium alloy, such as a nickel-chromium-aluminium alloy. Examples include NiCr20AlSilMnFe, NiCr6015, NiCr8020, NiCr3020. Finally, a copper-nickel alloy can also be used as a resistor material. However, the disclosure is not limited to the above-mentioned examples with regard to the resistor material.

The thickness of the flat support element and/or the flat resistor element is preferably less than 0.3 mm and greater than 0.5 mm.

In general, it should be mentioned that the resistor is preferably a low ohmic current-measuring resistor with a resistance value in the milliohm range. For example, the resistance value can be less than 500 mΩ, 200 mΩ, 50 mΩ, 30 mΩ, 20 mΩ, 10 mΩ, 5 mΩor 1 mΩ.

Furthermore, it should also be mentioned in general that the resistor is preferably an SMD resistor (SMD: surface mounted device).

In addition to the manufacturing method according to the disclosure described above, the disclosure also claims protection for a correspondingly manufactured resistor. It should be mentioned here that the finished resistor is characterized by the fact that it does not contain a trimming cut in the resistor element and the distance between the contact caps varies.

Other advantageous embodiments of the disclosure are characterized in the sub-claims or are explained in more detail below together with the description of the preferred embodiments of the disclosure with reference to the figures.

### BRIEF DESCRIPTION OF THE DISCLOSURE

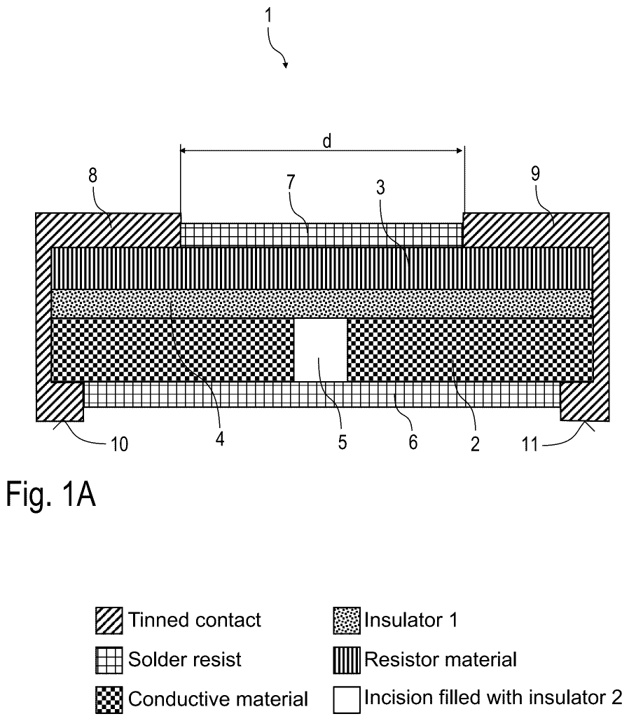

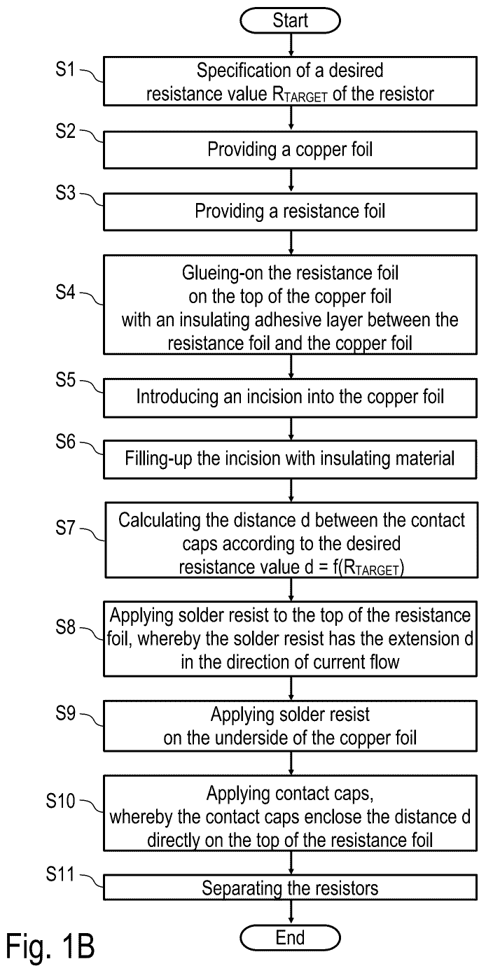

FIG. 1A shows a cross-sectional view of a current-measuring resistor according to the disclosure.

FIG. 1B shows a flow chart to illustrate the manufacturing method of the current-measuring resistor according to FIG. 1A.

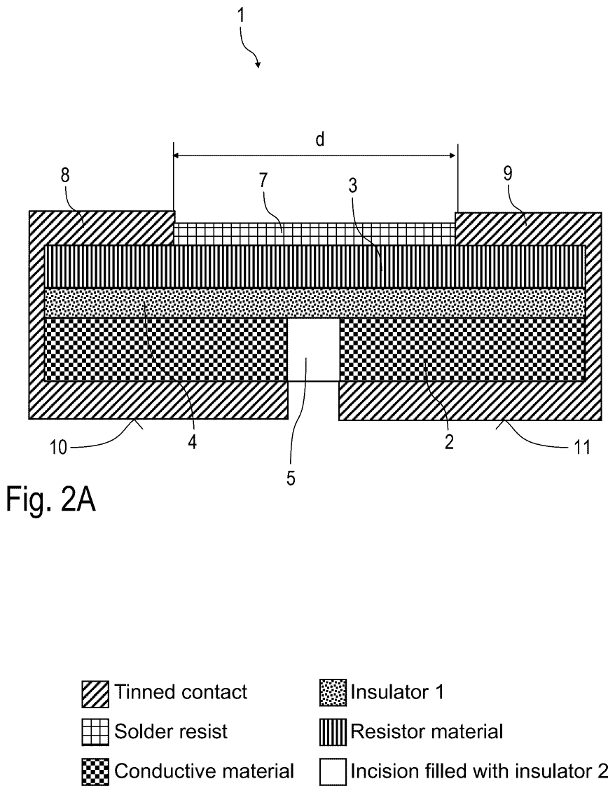

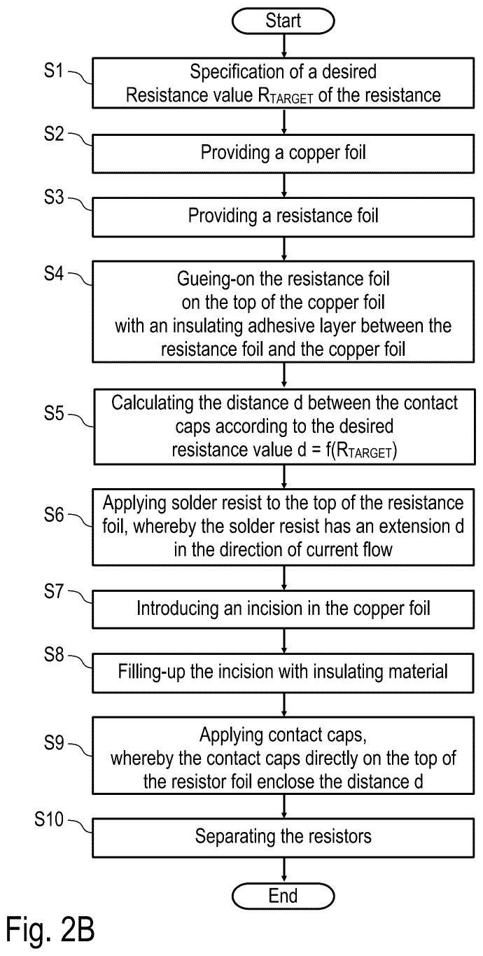

FIG. 2A shows a modification of FIG. 1A.

FIG. 2B shows a flow chart illustrating the manufacturing method of the current-measuring resistor according to FIG. 2A.

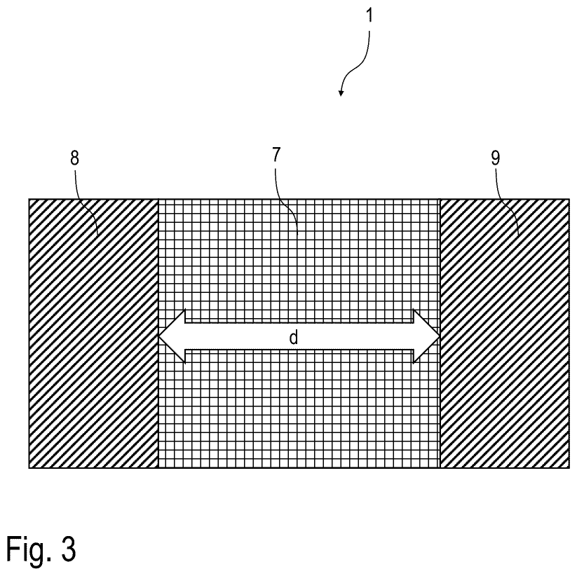

FIG. 3 shows a top view of the current-measuring resistors according to FIGS. 1A and 2A.

### DETAILED DESCRIPTION OF THE DISCLOSURE

In the following, the embodiment of a current-measuring resistor 1 according to the disclosure shown in FIG. 1A is first described. The structure and the technical principle of the current-measuring resistor 1 largely correspond to the known current-measuring resistor as described in WO 2008/055582 A1, so that the content of this publication can be attributed to the present description in its entirety. In the following, the current-measuring resistor 1 is therefore only briefly described in order to then go into the details of the adjustment of the resistance value according to the disclosure.

The current-measuring resistor 1 firstly comprises a support element 2, which in this example is made of a copper foil.

In addition, the current-measuring resistor 1 comprises a resistor element 3, which is made of a resistance foil in this embodiment.

The support element 2 is bonded to the resistor element 3 by an adhesive layer 4, as is known from the prior art. The adhesive layer 4 has two functions. Firstly, the adhesive layer 4 mechanically connects the resistor element 3 to the support element 2. Secondly, the adhesive layer 4 also forms an electrical insulation between the resistor element 3 and the support element 2.

There is an incision 5 in the metal support element 2 to prevent an electrical short circuit in the finished current-measuring resistor 1 via the metal support element 2. The incision 5 in the support element 2 is filled with an insulating material. On the one hand, filling the incision 5 with the insulating material improves the mechanical resilience of the finished current-measuring resistor 1. On the other hand, filling the incision 5 with the insulating material also improves the heat dissipation within the current-measuring resistor 1.

A solder resist 6 is applied to the underside of the current-measuring resistor 1.

In addition, a solder resist 7 is also applied to the upper side of the resistor element 3, whereby the solder resist 7 on the upper side of the resistor element 3 has an extension d along the direction of current flow in the finished current-measuring resistor 1.

Furthermore, the current-measuring resistor 1 has two contact caps 8, 9 at its opposite ends in the direction of current flow, which serve to make electrical contact with the current-measuring resistor 1. The contact caps 8, 9 enclose the current-measuring resistor 1 laterally both on the top and on the bottom. On the top side, the two contact caps 8, 9 reach up to the solder resist 7. This means that the extension d of the solder resist 7 defines the distance between the two contact caps 8, 9. This is significant because the distance d between the two contact caps 8, 9 defines the length of the current path that runs between the two contact caps 8, 9 through the resistor element 3. The distance d between the two contact caps 8, 9 thus also defines the resistance value. As part of the method according to the disclosure for adjusting the resistance value, the extension d of the solder resist 7 is therefore set with high precision, namely as a function of the desired resistance value of the finished current resistor 1.

Finally, it should also be mentioned that the current-measuring resistor 1 has contact surfaces 10, 11 on its underside, to which the current-measuring resistor 1 can be contacted on a printed circuit board, for example.

The flow chart shown in FIG. 1B is now described below, which illustrates the manufacturing method for the current-measuring resistor 1 shown in FIG. 1A.

In a first step S1, a desired resistance value R_{TARGET} is specified for the current-measuring resistor 1.

In a step S2, the support element 2 is then provided in the form of a copper foil.

In step S3, the resistor element 3 is then provided in the form of a resistance foil.

The next step S4 then provides for the resistance foil to be glued to the upper side of the copper foil with the electrically insulating adhesive layer 4 between the support element 2 and the resistor element 3.

In the next step S5, the incision 5 is then made in the copper foil, which forms the support element 2.

In the next step S6, the incision 5 is then filled with the insulating material.

In a step S7, the distance d between the contact caps 8, 9 is calculated as a function of the desired resistance value R_{TARGET} so that the desired resistance value R_{TARGET} is maintained as precisely as possible.

In the next step S8, the solder resist 7 is then applied to the top of the resistance foil, whereby the extension d of the solder resist 7 is maintained as precisely as possible. The solder resist 7 is therefore applied to the top of the resistance foil with a high degree of positioning accuracy so that the desired extension d is maintained as precisely as possible.

In the next step S9, the solder resist 6 is applied to the underside of the copper foil.

In a step S10, the opposing contact caps 8, 9 are then applied, whereby the desired distance d between the contact caps 8, 9 is then set directly on the upper side of the resistance foil. The contact caps 8, 9 therefore do not have to be applied with a high degree of positioning accuracy, as the distance d was previously set by the extension of the solder resist 7.

In the next step S11, the current-measuring resistors 1 are then separated.

The embodiment shown in FIGS. 2A and 2B largely corresponds to the embodiment shown in FIGS. 1A and 1B, so that reference is made to the above description in order to avoid repetition.

A special feature of this embodiment is that no solder resist is applied to the underside of the current-measuring resistor 1.

Another special feature of this design example is that the contact caps 8, 9 on the underside of the current-measuring resistor 1 extend inwards as far as the incision 5.

Otherwise, reference is made to the above description in order to avoid repetition.

The disclosure is not limited to the preferred embodiments described above. Rather, the disclosure also includes variants and modifications which also make use of the inventive concept and therefore fall within the scope of protection. In particular, the disclosure also claims protection for the subject matter and the features of the dependent claims independently of the respective claims referred to and in particular also without the features of the main claim. The disclosure thus comprises various aspects of the disclosure which enjoy protection independently of each other.

### LIST OF REFERENCE SIGNS

1 Current-measuring resistor
2 Support element made of copper foil
3 Resistor element made of a resistance foil
4 Adhesive layer
5 Incision in the support element
6 Solder resist on the underside
7 Solder resist on the top side
8, 9 Contact caps of the current-measuring resistor
10, 11 Contacting surfaces of the contact caps on the underside of the current-measuring resistor
d Distance between the contact caps

1. A manufacturing method for an electrical resistor, comprising the following steps:
providing a flat support element made of an electrically conductive conductor material and having an upper side and a lower side;
providing a flat resistor element made of a resistor material;
flatly applying the flat resistor element to the upper side of the flat support element with an electrically insulating layer between the flat resistor element and the flat support element;
electrically contacting the flat resistor element with two contact caps,
wherein the two contact caps consist of an electrically conductive conductor material, rest directly on the upper side of the flat resistor element, lie opposite one another with respect to the direction of current flow in the resistor, and enclose a distance between them along the direction of current flow in the resistor directly on the upper side of the flat resistor element, and
setting a desired resistance value (R_{TARGET}) of the resistor; and
adjusting the resistance value of the resistor by adjusting the distance between the contact caps directly on the upper side of the flat resistor element, the distance being adjusted as a function of the desired resistance value (R_{TARGET}).

2. The manufacturing method according to claim 1, further comprising:
applying solder resist directly to the upper side of the flat resistor element before contacting with the two contact caps, the solder resist having an extension along the direction of current flow in the resistor, and
applying the two contact caps to the upper side of the flat resistor element after applying the solder resist to the upper side of the flat resistor element so that the extension of the solder resist defines the distance of the two contact caps directly on the upper side of the flat resistor element.

3. The manufacturing method according to claim 2, wherein the extension of the solder resist along the direction of current flow in the resistor is set with a first positioning accuracy when the solder resist is applied to the upper side of the flat resistor element,
wherein, the distance between the two contact caps along the direction of current flow in the resistor is set with a second positioning accuracy when the two contact caps are applied, and
wherein the first positioning accuracy is greater than the second positioning accuracy.

4. The manufacturing method according to claim 1, further comprising:
applying solder resist to the lower side of the flat support element between the two contact caps.

5. The manufacturing method according to claim 4, wherein the solder resist is applied to the lower side of the flat support element before the two contact caps are applied to the resistor or after the two contact caps have been applied to the resistor.

6. The manufacturing method according to claim 1, further comprising:
making an incision in the flat support element,
wherein the incision separates the flat support element into two parts, so that the incision prevents a short circuit across the flat support element.

7. The manufacturing method according to claim 6, further comprising:
filling the incision with an electrically insulating material.

8. The manufacturing method according to claim 6, wherein the incision is made in the flat support element before the solder resist has been applied to the lower side of the flat support element so that the solder resist also covers the incision.

9. The manufacturing method according to claim 1,
wherein the flat support element is produced from a metal foil, in particular from a copper foil,
wherein the flat resistor element is produced from a resistance foil, and
wherein the metal foil is bonded to the resistance foil over its entire surface by an adhesive layer, the adhesive layer forming the electrically insulating layer.

10. The manufacturing method according to one of claim 6, wherein the two contact caps embrace the resistor on its upper side and on its lower side, the two contact caps on the lower side of the resistor extend as far as the incision in the support element, and/or the conductor material of the two contact caps contains tin.

11. The manufacturing method according to claim 1:
(a) wherein the resistor material is selected from the group consisting of a copper-manganese alloy, a nickel-chromium alloy, and a copper-nickel alloy:
(b) wherein the flat support element has a thickness which is less than 0.3 mm and/or greater than 0.5 mm,
(c) wherein the flat resistor element has a thickness which is less than 0.3 mm and/or greater than 0.05 mm,
(d) wherein the conductor material of the two contact caps is copper, a copper alloy, aluminum, or an aluminum alloy,
(e) wherein the resistor has a resistance value in the milliohm range,
(f) wherein the resistor material has a greater specific electrical resistance than the conductor material,
and/or
(g) wherein the resistor is an SMD resistor.

12. A resistor manufactured by the manufacturing method according to claim 1.

13. The resistor according to claim 12, wherein the resistor does not include a trim cut in the flat resistor element.

14. The manufacturing method according to claim 1, wherein the electrical resistor is a low-impedance current-measuring resistor.

15. The manufacturing method according to claim 1, wherein the resistor material is selected from the group consisting of CuMn12Ni, CuMn7Sn, and CuMn3.

16. The manufacturing method according to claim 1, wherein the resistor material is selected from the group consisting of NiCr20AlSiIMnFe, NiCr6015, NiCr8020, and NiCr3020.

17. The manufacturing method according to claim 1, wherein the resistor has a resistance value of less than 500 mΩ.

18. The manufacturing method according to claim 1, wherein the resistor has a resistance value of less than 20 mΩ.

19. The manufacturing method according to claim 9, wherein the metal foil is a copper foil.
